(19) United States
(12) Patent Application Publication
(10) Pub. No.: US 2006/0065517 A1
(43) Pub. Date: Mar. 30, 2006

(54) Target and method of diffusion bonding target to backing plate

(75) Inventors: Eugene Y Ivanov, Grove City, OH (US); Harry W Conard, Orient, OH (US)

Correspondence Address: WEGMAN, HESSLER & VANDERBURG, 6055 ROCKSIDE WOODS BOULEVARD, SUITE 200, CLEVELAND, OH, 44131, US

(73) Assignee: Tosoh SMD, Inc., Grove City, OH (US)

(21) Appl. No.: 10/514,802

(22) PCT Filed: Jun. 11, 2003
(86) PCT No.: PCT/US03/18440

§ 371 Date: Nov. 15, 2004

Related U.S. Application Data
(60) Provisional application No. 60/388,780, filed on Jun. 14, 2002.

(51) Int. Cl. C23C 14/00; C23C 14/32

(52) U.S. Cl. 204/192.12; 204/298.12

(57) ABSTRACT

Sputter target assemblies (10) and methods of making the sputter target assemblies in which the HIP processes conventionally used are minimized, or eliminated, while producing higher yields of sputter target assemblies in less time. In one instance the sputter target assemblies include a single, or multiple, layered interlayer (14, 16) between the target and backing plate (18) in order to achieve intermetallic diffusion bonds between adjacent layers during a single HIP process. A mechanical interlock between the target (12) and backing plate is also achieved preferably during a single HIP process. In another instance, the target and backing plate are welded directly together by electron beam welding, and the interlayer and HIP process are omitted. In either case, the process for making the sputter target assembly is shortened, rendering it less expensive and subject to less failures, while achieving assemblies having robust strength.

### CROSS-REFERENCE TO RELATED APPLICATION

This application claims the benefit of U.S. Provisional Application Ser. No. 60/388,780, filed Jun. 14, 2002.

### BACKGROUND OF THE INVENTION

1. Field of Invention

This invention relates to sputter target assemblies and methods of making the same.

2. Description of Related Art

Sputter targets of high purity metals or metal alloys attached to backing plates are typically used to deposit thin films on substrates such as, for example, semiconductor devices. In some methods, high purity metal and metal alloy sputter targets historically have been bonded to backing plates by a two step diffusion bonding process. The two step operation requires, for example, diffusion bonding a foil to the target by subjecting the foil/target combination to hot isostatic pressing (HIP). Thereafter, the diffusion bonded foil/target is machined, if desired, and diffusion bonded to the backing plate by another HIP process. Other techniques include separately soldering the foil/target combination to the backing plate.

A variety of bond types and structures are shown for example in U.S. Pat. No. 6,376,281; WO 98/41669; U.S. Pat. Nos. 5,693,203; and 5,224,556.

It is preferable to minimize the amount of processing a sputter assembly is subjected to. It is similarly preferable to produce sputter target assemblies in less time than is achieved using conventional methods. Even further still, it is preferable to provide sputter target assemblies having robust bond strength while minimizing assembly production time and effort.

### SUMMARY OF THE INVENTION

One aspect of the invention pertains to a sputter target assembly comprised of a target, an interlayer, and a backing plate that, in one aspect of the invention, are bonded together during a single HIP process. The interlayer is thus placed between the target and backing plate and diffusion bonded to the adjacent target and backing plate materials. The interlayer may be a single layer comprised of a metal alloy, for example, or may be multiple layers each comprised of a distinctly different material. The target and backing plate interface at a substantially single level, or may interface at multiple levels, depending on the formations of the target and backing plate. In either case, the interlayer forms intermetallic diffusion bonds between adjacent layers.

In an especially preferred embodiment, the invention separately provides a target comprised of tantalum, a first interlayer comprised of aluminum adjacent the target, a second interlayer comprised of titanium adjacent the first interlayer, and a backing plate comprised of copper, or alloy thereof, adjacent the second interlayer. The adjacent layers are subjected to a single HIP process, whereby the adjacent layers diffusion bond to one another to form a robust sputter target assembly.

This invention separately provides a sputter target assembly comprising a mechanical bond formed between the target and backing plate, in addition to the diffusion bonds between adjacent layers, to further secure the sputter target assembly together. A central stud is provided on one of the target and backing plate and fits into a corresponding recess provided in the other of the target and backing plate. The recess form a negative or re-entrant angle due to outwardly flaring side walls of the recess extending through the thickness of the target or backing plate the recess is provided in. The negative angle is filled with material during HIP processing to form the mechanical interlock between the target and backing plate. Similar negative angles are provided along a perimeter of each level of the target or backing plate that similarly fill with material to form additional mechanical interlocks between the target and backing plate during HIP processing. The resulting sputter target assembly thus comprises intermetallic diffusion bonds between the target, the interlayer, and the backing plate, as well as mechanical interlocks between the target and the backing plate. In various exemplary embodiments of the invention, the target or backing plate having the negative angles formed therein is a single level, whereas in other exemplary embodiments of the invention the target or backing plate having the negative angles formed therein is comprised of multiple levels.

In still other exemplary embodiments of the invention, the sputter target assemblies formed by the single HIP processing may comprise targets and backing plates having corresponding grooves providing increased contact surface area between adjacent layers. An increased amount of intermetallic diffusion bonds thus form between adjacent layers due to the increased contact surface area.

Another aspect of the invention relates to a sputter target assembly comprised of a target and a backing plate welded directly to one another by electron beam welding. The electron beam welding causes a weld bond to occur between the materials of the target and the backing plate. The weld bond may occur, for example, at the outer perimeter of the target and backing plate. The otherwise immiscible materials comprising the target and backing plate become miscible in a liquid state when subjected to the electron beam welding, thereby permitting the weld bond to form between the target and backing plate. In addition, grooves provided on the target and backing plate are pressed together and help to further secure the target and backing plate to one another as well.

These and other features and advantages of this invention are described in, or are apparent from, the following detailed description of various exemplary embodiments of the systems and methods according to this invention.

### BRIEF DESCRIPTION OF THE DRAWINGS

Various exemplary embodiments of the systems and methods of this invention will be described in detail with reference to the following figures, wherein:

FIG. 1 illustrates a first exemplary embodiment of a sputter target assembly made in accordance the invention;

FIG. 2 illustrates an exploded view of the sputter target assembly of FIG. 1;

FIG. 3 illustrates the sputter target assembly of FIG. 1 wherein the sides of the interlayer foils are not exposed;

FIG. 4 illustrates a second exemplary embodiment of a sputter target assembly according to the invention having diffusion bonding between interlayers and a mechanical interlock between multiple levels;

FIG. 5 is a third exemplary embodiment of a substantially single level sputter target assembly having diffusion bonds and mechanical interlocks;

FIG. 6 illustrates an exemplary target having grooves and ridges for making a sputter target assembly in accordance with the invention;

FIG. 7 illustrates an exemplary backing plate having grooves and ridges corresponding to the grooves and ridges of the target of FIG. 7; and

FIG. 8 illustrates a fourth exemplary embodiment of a sputter target assembly made with a weld bond in accordance with the invention.

### DETAILED DESCRIPTION OF EXEMPLARY EMBODIMENTS

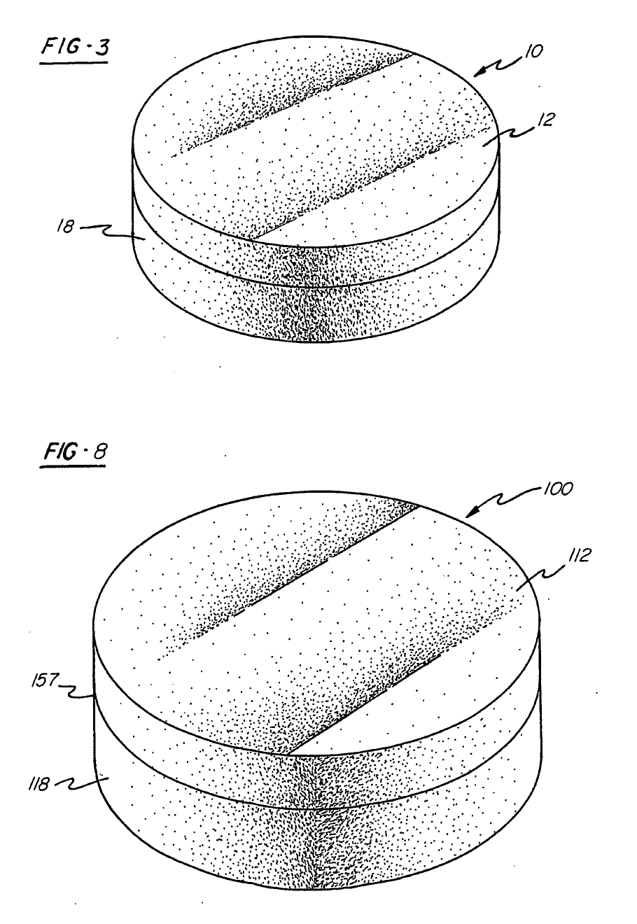

FIG. 1 shows a sputter target assembly 10 according to a first exemplary embodiment of the invention. The sputter target 10 is formed by a target 12, a first interlayer 14, a second interlayer 16, and a backing plate 18. As shown in FIG. 1, the first layer is adjacent the target and the second interlayer, and the second interlayer is adjacent the backing plate and the first interlayer. The first interlayer is comprised of a material that diffusion bonds to the target and the second interlayer, whereas the second interlayer is comprised of a material that diffusion bonds to the first interlayer and the backing plate. The sides of the various layers are exposed in FIG. 1 to illustrate more clearly the various layers of materials comprising this embodiment of the invention. When fully assembled, the first and second interlayers 14, 16 of the sputter target assembly are not exposed, as shown in FIG. 3.

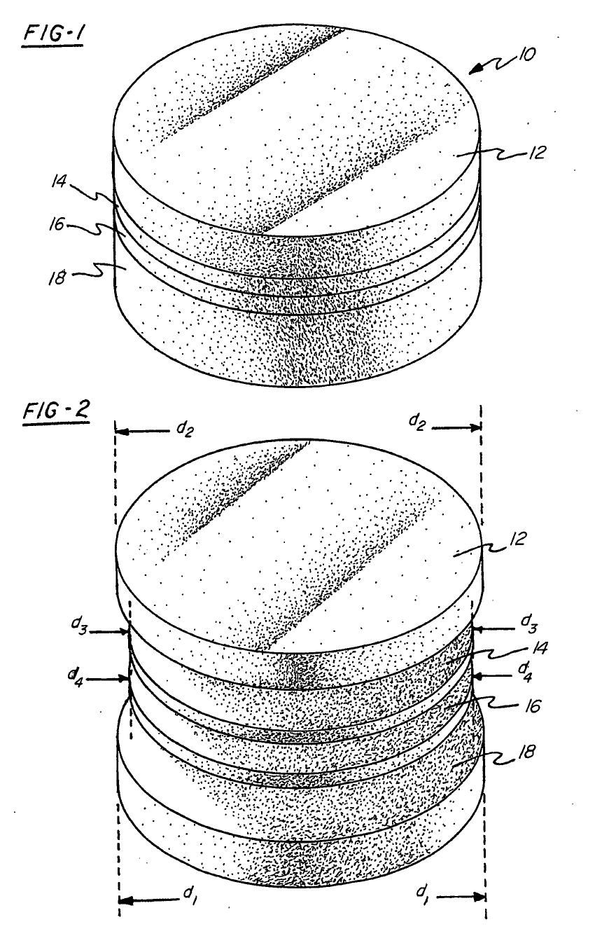

FIG. 2 is an exploded view of the components of the target assembly 10 shown in FIG. 1. More particularly, FIG. 2 shows that the diameters d₁ of the backing plate and the diameter d₂ of the target are approximately the same, whereas the diameters d₃ and d₄ of the first and second interlayers, respectively, are less than the diameters d₁ and d₂ of the target and backing plate. Thus, the relationship of the various layers of the embodiment shown in FIG. 2 is (d1=d2)>(d3=d4). Although the thickness of the interlayer in FIGS. 1 and 2 may vary, a preferred thickness of the first interlayer is 0.015 inches, and a preferred thickness of the second interlayer is 0.001 inches.

The target and backing plate shown in FIGS. 1 and 2 are each shown as a substantially single level such that the interface between the target and backing plate occurs at the plane formed by the mating surfaces and the interlayer when the target and backing plate are joined. Thus the first and second interlayers generally overlie substantially the entire mating surface of the respective target and backing plate. The adjacent layers thus assembled, are placed in a HIP can and subjected to a single HIP process. As a result of the HIP process, diffusion bonds form between the adjacent layers in order to form one exemplary embodiment of the sputter target assembly according to the invention.

Although the sputter target assembly described with respect to FIGS. 1 and 2 show first and second interlayers, the assembly may also be formed using a single interlayer. If the interlayer is a single layer, it is preferably comprised of a metal alloy that will form diffusion bonds, ideally equally well, with the adjacent target and backing plate materials. This contrasts from the first and second interlayers shown in FIGS. 1 and 2 that are each comprised of distinctly different materials such that the first interlayer forms diffusion bonds with the target and the second interlayer, and the second interlayer forms diffusion bonds with the backing plate and the first interlayer. Stated differently, in the embodiment shown in FIGS. 1 and 2, neither of the first and second interlayers form diffusion bonds directly with both the target and the backing plate, whereas when a single interlayer is used, the single interlayer must diffusion bond directly to both the target and the backing plate. In either case, however, the single or multiple layered interlayer forms intermetallic diffusion bonds between adjacent layers.

In a preferred embodiment of the invention, the target is comprised of tantalum, the first interlayer is comprised of aluminum, the second interlayer is comprised of titanium, and the backing plate is comprised of copper, or an alloy thereof, for example copper-1% chromium or copper-zinc. Previous experience has shown that tantalum is separately successfully diffusion bonded to aluminum, aluminum is separately successfully diffusion bonded to titanium, and titanium is separately successfully diffusion bonded to copper-1% chromium. Thus, the preferred embodiment of the invention combines these materials in adjacent layers to diffusion bond a tantalum target to a copper-1% chromium backing plate in one step. The standard HIP process for Ti/Al6061 diffusion bonding, for example, may be used.

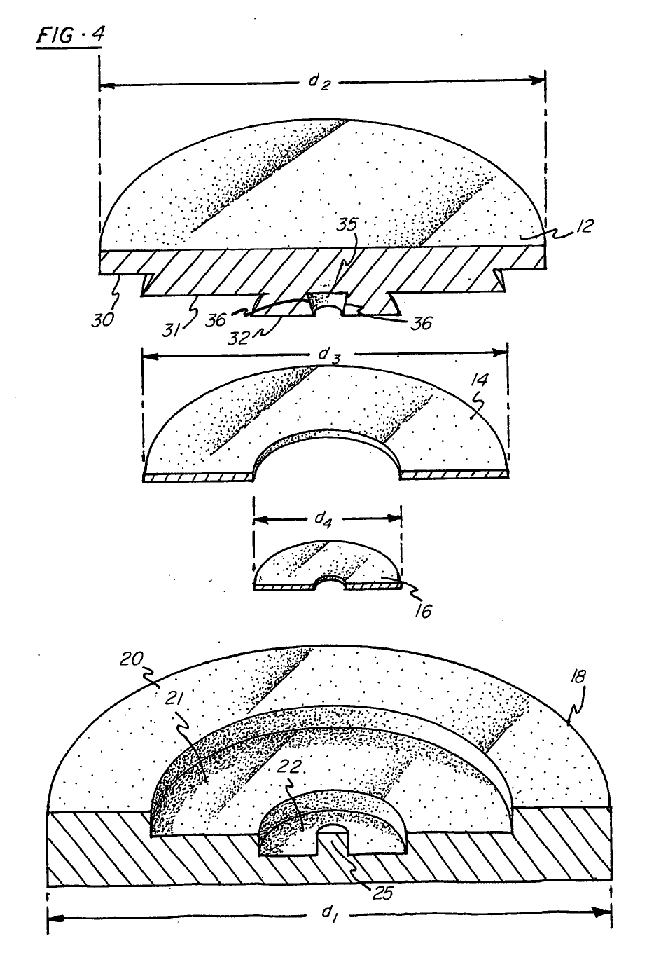

As a result of diffusion bonding the adjacent layers comprised of tantalum-aluminum-titanium-(copper-1% chromium) as in the preferred embodiment, brittle Al/Cu compounds between the aluminum first interlayer and the backing plate are less likely to occur even if ductile fractures in the aluminum interlayer were to occur, for instance. Rather, as shown in FIG. 4, the titanium second interlayer 16 remains in tact, minimizing the likelihood of producing such Al/Cu compounds between the aluminum interlayer 14 and backing plate 18.

Maintaining the integrity of the titanium interlayer is important to minimize, or ideally to prevent, contacting the aluminum interlayer, for example, with the copper backing plate. Contact of the aluminum interlayer with the copper backing plate would weaken the bond strength of the sputter assembly as a result of the brittle Al/Cu compounds that would form in the absence of the titanium interlayer, for example. The preferred embodiment of the invention therefore provides a sputter target assembly with increased strength and stability using a single HIP process as a result of the adjacent tantalum-aluminum-titanium-copper backing plate layers.

FIG. 4 illustrates another exemplary embodiment of the sputter target assembly according to the invention. The assembly shown in FIG. 4 is comprised of a multi-level target 12 diffusion bonded to a multi-level backing plate 18 having first and second interlayers 14 and 16 therebetween. As shown in FIG. 4, the diameter d1 of the backing plate is slightly larger than the diameter d2 of the target, the diameter d2 of the target is slightly larger than the diameter d3 of the first interlayer, and the diameter d3 of the first interlayer is slightly larger than the diameter d4 of the second interlayer. Thus the relationship of the various layers in the sputter target assembly of FIG. 4 is d4<d3<d2<d1.

The backing plate 18 of FIG. 4 is provided, for example, with three layers 20, 21, 22 and the target is provided, for example, with three levels 30, 31, 32. Level 21 of the backing plate is recessed from the mating surface of the backing plate to form a cavity in which the first interlayer 14 and level 31 of the target is received. Level 22 of the backing plate is recessed even further from the mating surface of the backing plate to form a cavity in which the second interlayer 16 and level 32 is received. The backing plate is provided with a central stud 25 projecting through holes in each of the first and second interlayers and into a recess 35 extending into the target through level 32. Side walls 36 of the recess 35 flare outwardly to form a negative angle into which backing plate materials will flow during HIP processing. The perimeters of each level 21 and 22 of the target are similarly negatively or re-entrantly angled, and will be similarly filled with molten materials during HIP processing. The filling of the negative angles formed in the recess and perimeters of the target levels during HIP processing form mechanical interlocks between the target and backing plate. When fully assembled, the various levels fit flush with one another such that the assembly appears as shown in FIG. 3.

As in earlier described embodiments, preferably the target is comprised of tantalum, the first interlayer is comprised of aluminum, the second interlayer is comprised of titanium, and the backing plate is comprised of copper, or an alloy thereof, preferably copper-1% chromium or copper-zinc. As a result, a multi-level sputter target assembly may be achieved as shown in FIG. 4, wherein diffusion bonds form between the adjacent layers during HIP processing in order to form the desired sputter target assembly. As also described earlier, the first and second interlayers may instead be comprised of a single layer comprised of a metal alloy that forms bonds directly with the various levels of the target and backing plate, ideally equally well. In either case, the assembly includes both diffusion bonds and mechanical interlocks between adjacent layers.

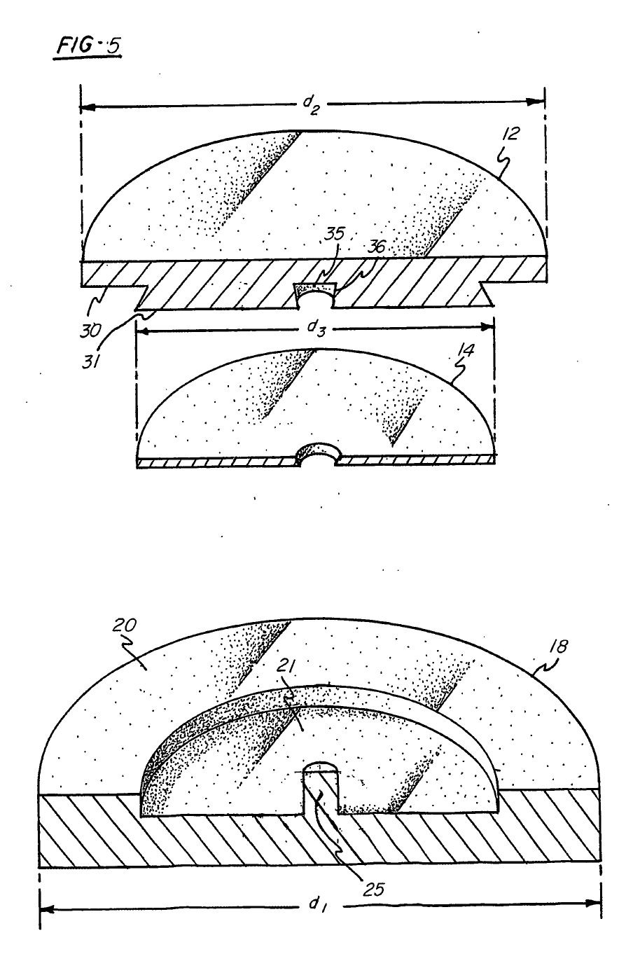

FIG. 5 shows another exemplary embodiment of a sputter target assembly according to the invention. The embodiment shown in FIG. 5 is comparable to that shown in FIG. 4, except that the target 12 is a single level, level 31, in FIG. 5, rather than multiple levels, levels 31 and 32, as in FIG. 4 and only a single interlayer 14 is used in the embodiment shown in FIG. 5. The negative angled recess and negative angled perimeter at the single level (level 31) of the target in FIG. 5 are similarly filled with material during HIP processing to achieve mechanical interlocks in addition to the diffusion bonds formed between the adjacent layers as in the earlier described embodiment shown in FIG. 4.

The diffusion bonding that occurs between the target and backing plate materials in all of the exemplary embodiments described thus far is achieved due to the materials used to comprise the various layers, and due to the time, temperature and pressure conditions of the HIP process and materials to join together through diffusion bonding and mechanical interlocking. In addition to the chemical nature of the intermetallic diffusion bonds formed exclusively between the adjacent target, first interlayer, second interlayer, and backing plate layers in some embodiments of the invention, mechanical interlocks between the target and backing plate also occurs in other embodiments of the invention as the heated plastic materials cool and harden around the negative angles. The combination of the intermetallic diffusion bonding and mechanical interlocking provides a robust strength to the sputter target assembly that is accomplished relatively quickly with a single HIP process.

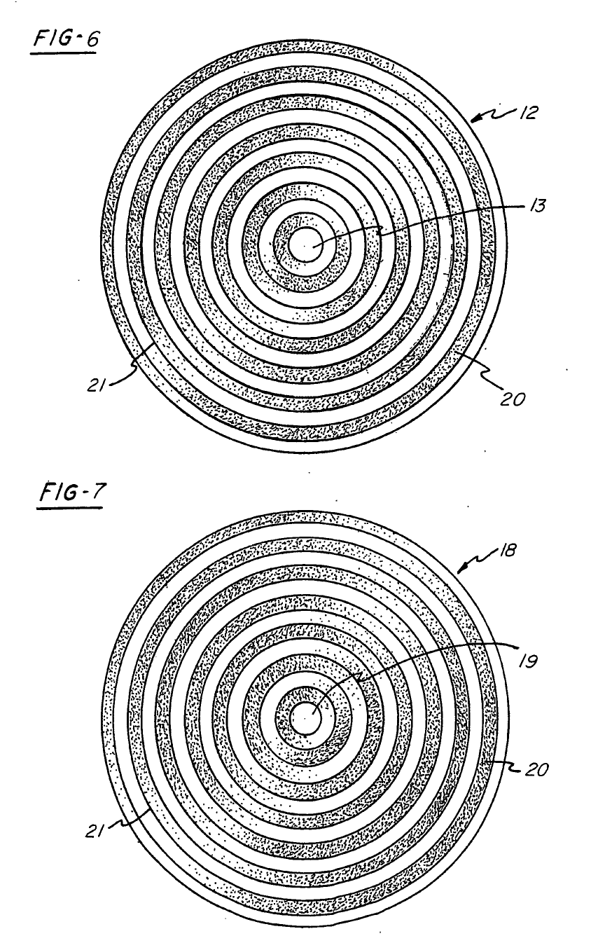

FIGS. 6 and 7 show a modification to the exemplary embodiments shown in FIGS. 1-5, wherein the target 12 (FIG. 6) and backing plate 18 (FIG. 7) are provided with corresponding grooves 40 and ridges 41 on those respective sides of the target and backing plate that are adapted to mate with the interlayer(s). The ridges 41 may be slightly larger than the width of the grooves 40 so as to provide an interference fit when the target and backing plate are pressed together, if desired. More importantly, however, the grooves and ridges increase the contact surface area between the adjacent layers of the sputter target assembly. Thus, in the embodiment shown in FIGS. 1-5, the sputter target assembly tends to have more intermetallic diffusion bonds due to the increased surface area provided by the grooves and ridges, thus rendering a still stronger assembly using a single HIP process. The grooves and ridges may be concentric as shown in FIGS. 6 and 7, however, the artisan will appreciate that the grooves and ridges need not be concentric. Rather, any pattern increasing the contact surface area between the adjacent layers that does not inhibit the diffusion bonding and mechanical bonding desired in the various exemplary embodiments discussed is contemplated.

Although the artisan will appreciate that the target, first and second interlayers, and backing plate may be comprised of many alternative combinations of materials to achieve the intermetallic diffusion bonds between the adjacent layers, the exemplary materials discussed herein with respect to the first and second exemplary embodiments of the invention comprise a Ta target, an Al first interlayer, a Ti second interlayer, and a Cu-1% Cr backing plate. Of course, the artisan will appreciate that the first and second interlayers comprised of distinctly different materials, may instead be a single interlayer comprised of a metal alloy, such as, for example, silver-copper-tin or silver-copper-tin-zinc. The single metal alloy interlayer would thus lie between the target and backing plate. The artisan will also appreciate, with respect to those embodiments having a mechanical interlock, that the stud and recess are a corresponding pair that may instead be provided in inverse order on the target and backing plate provided the corresponding pair exists between the target and backing plate, and the various layers may be inversely oriented on the other of the target and backing plate provided corresponding cavities are provided to accommodate the different adjacent layers is provided to form the assembly with the intended mechanical interlocks in those embodiments.

The general method for forming the sputter target assembly of the first and second embodiments is generally as follows:
a. provide a backing plate comprised of a first material and a mating surface;
b. provide a target comprised of a second material and a mating surface;
c. provide an interlayer between the target and backing plate, the interlayer being comprised of a material different than the first and second material;
d. place the target, interlayer, and backing plate as adjacent layers into a HIP can and subject the adjacent layers preferably to a single HIP processing step to form an assembly;
e. form intermetallic diffusion bonds between the adjacent layers; and
f. remove the assembly from the HIP can.

Of course, the target and backing plate provided in steps a and b may be a multi-level combination wherein the variously diametered adjacent layers are accommodated in corresponding levels of one of the target and backing plate. In those embodiments requiring the mechanical interlock, a central stud and corresponding recess is provided on the target and backing plate, and the interlayer(s) is provided with the necessary hole(s) to accommodate the central stud passing therethrough to seat into the recess. The perimeter of each layer of the target, for example, is also negative angled. The mechanical interlock is thus formed between steps e and f above. The interlayer provided in step c may be comprised of multiple layers of different materials. In addition, the target and backing plate may be provided with grooves and ridges to increase the surface area whereat intermetallic diffusion bonds are formed between the various layers during the HIP processing.

FIG. 8 shows another exemplary embodiment of a sputter target assembly 100 according to the invention. The sputter target assembly 100 is comprised of a target 112 and a backing plate 118. Thus, the interlayer between the target and backing plate, as in the earlier-described embodiments, is omitted in the embodiment shown in FIG. 8.

The target 112 and backing plate 118 may be provided with corresponding grooves and ridges similar to those shown in FIGS. 5 and 6. However, the target 112 and backing plate 118 of the third embodiment are not provided with the central stud and recess described in the first and second embodiments.

The target 112 and backing plate 118 of the third embodiment are bonded together by electron beam welding. Preferably, the weld bonding occurs such that the outer perimeters of the target and backing plate are welded together. The electron beam welding liquefies the otherwise immiscible materials comprising the target and backing plate, and welds he target and backing plate together.

In addition, the corresponding grooves and ridges provided on the target and backing plate are pressed together to form an interference fit between the target and backing plate when the target and backing plate are pressed together. As discussed before, the artisan will appreciate that the grooves and ridges may be, but need not be, concentric about the mating surface of the target and backing plate. Rather, the grooves and ridges may be any pattern corresponding to one another so as to achieve the desired interference fit between the target and backing plate in addition to the weld bonding of the third exemplary embodiment. Thus, the third exemplary embodiment omits the HIP processing and the interlayer(s), while still yielding a sputter target assembly of robust strength as a result of the weld bonding and interference fit that occurs.

The method for forming the sputter target assembly of the third embodiment is generally as follows:
a. provide a target comprised of a first material and a mating surface;
b. provide a backing plate adjacent the target, the backing plate being comprised of a second material having a mating surface;
c. press the mating surfaces of the target and backing plate together; and
d. subject the target and backing plate assembly to electron beam welding to weld the first and second materials of the target and backing plate.

As stated earlier with respect to the first and second embodiments, the artisan will appreciate that the target and backing plate may be comprised of many alternative combinations of materials to achieve the diffusion bonds and interference fit between the target and backing plate, although the description of the third exemplary embodiment contemplates, for illustrative purposes only, that a Ta target 112 and a Cu-1% Cr backing plate 118 are used. Grooves and ridges, or other patterned mating surfaces, may be provided on the target and backing plate to achieve interference fit between the target and backing plate in addition to the weld bonding of step d. Further, step d preferably welds the target and backing plate along an outer perimeter thereof.

While this invention has been described in conjunction with the specific embodiments described above, it is evident that many alternatives, combinations, modifications, and variations are apparent to those skilled in the art. Accordingly, the preferred embodiments of this invention, as set forth above are intended to be illustrative, and not limiting. Various changes can be made without departing from the spirit and scope of this invention.

What is claimed is:

1. A sputter target assembly comprising:
a target comprised of a first material and having a mating surface;
an interlayer comprised of a second material;
a backing plate comprised of a third material and having a mating surface,
wherein the interlayer is intermetallically diffusion bonded with the mating surfaces of the target and backing plate during a HIP process.

2. The sputter target assembly of claim 1, wherein the first material is tantalum or an alloy thereof, the third material is copper or an alloy thereof, and the second material is a metal alloy diffusion bondable to the first and third materials.

3. The sputter target assembly of claim 2, wherein the second material is a metal alloy comprised of silver-copper-tin-zinc.

4. The sputter target assembly of claim 2, wherein a portion of the mating surfaces of the target and backing plate abut one another when diffusion bonding is achieved.

5. The sputter target assembly of claim 2, wherein the interlayer is comprised of a first interlayer and a second interlayer.

6. The sputter target assembly of claim 5, wherein the target is comprised of tantalum, the first interlayer is comprised of aluminum, the second interlayer is comprised of titanium, and the backing plate is comprised of copper or an alloy thereof.

7-11. (canceled)

12. A method of making a sputter target assembly comprising:
a. providing a target comprised of a first material and having a mating surface;
b. providing an interlayer comprised of a second material adjacent the mating surface of the target;
c. providing a backing plate comprised of a third material and having a mating surface, the mating surface of the backing plate being adjacent the interlayer;
d. placing the adjacent target, interlayer, and backing plate assembly into a HIP can and subjecting the assembly to a HIP process;
e. forming intermetallic diffusion bonds between the adjacent layers, wherein the interlayer diffusion bonds to the target and the backing plate; and
f. removing the assembly from the HIP can.

13. The method of claim 12, wherein the first material is tantalum or an alloy thereof, the third material is copper or an alloy thereof, and the second material is a metal alloy diffusion bondable to the first and third materials.

14. The method of claim 13, wherein the second material is a metal alloy comprised of silver-copper-tin-zinc.

15. The method of claim 13, wherein the target and backing plate directly contact one another at a perimeter of the target and backing plate when diffusion bonding is achieved.

16. (canceled)

17. The method of claim 16, wherein the interlayer is comprised of a first interlayer and a second interlayer and wherein the target is comprised of tantalum, the first interlayer is comprised of aluminum, the second interlayer is comprised of titanium, and the backing plate is comprised of copper or an alloy thereof.

18-22. (canceled)

23. A sputter target assembly comprising:
a target comprised of a first material and a mating surface;
an interlayer comprised of a second material;
a backing plate comprised of a third material and a mating surface,
wherein the interlayer is intermetallically diffusion bonded with the mating surfaces of the target and backing plate and the target and backing plate are mechanically interlocked during a HIP process.

24. The sputter target assembly of claim 23, wherein one of the target and backing plate further comprises a central stud received by a corresponding recess on the other of the target and backing plate, the central stud passing through a hole provided in the interlayer.

25. The sputter target assembly of claim 24, wherein the recess forms a negative angle that is filled with material from among the first, second and third materials during the HIP process to achieve one of the mechanical interlocks.

26. The sputter target assembly of claim 25, wherein the target further comprises a multi-level mating surface and the backing plate further comprises a multi-level mating surface corresponding to the mating surface of the target.

27. The sputter target assembly of claim 26, wherein an outer perimeter of one of the target and backing plate forms a negative angle on each of the multi-levels thereof, which negative angles are filled with the materials during the HIP process to achieve another mechanical interlock.

28. The sputter target assembly of claim 24, wherein the first material is tantalum or an alloy thereof, the third material is copper or an alloy thereof, and the second material is a metal alloy diffusion bondable to the first and third materials.

29. The sputter target assembly of claim 28, wherein the second material is a metal alloy comprised of silver-copper-tin-zinc.

30. (canceled)

31. The sputter target assembly of claim 23, wherein the interlayer is comprised of a first interlayer and a second interlayer, wherein the target is tantalum, the first interlayer is aluminum, the second interlayer is titanium, and the backing plate is copper, or an alloy thereof.

32-36. (canceled)

37. A method of making a sputter target assembly comprising:
a. providing a target comprised of a first material and having a mating surface;
b. providing an interlayer comprised of a second material adjacent the mating surface of the target;
c. providing a backing plate comprised of a third material and having a mating surface, the mating surface of the backing plate being adjacent the interlayer;
d. placing the adjacent target, interlayer, and backing plate assembly into a HIP can and subjecting the assembly to a HIP process;
e. forming intermetallic diffusion bonds between the adjacent layers;
f. forming a mechanical interlock between the target and backing plate, wherein the interlayer diffusion bonds to the target and the backing plate; and
g. removing the assembly from the HIP can.

38. The method of claim 37, further comprising providing one of the target and backing plate further with a central stud received by a corresponding recess on the other of the target and backing plate, wherein during formation of said diffusion bonds the central stud passes through a hole provided in the interlayer.

39. The method of claim 38, wherein the recess forms a negative angle that is filled with materials from among the first, second and third materials to achieve one of the mechanical interlocks during the HIP process.

40-58. (canceled)
